(19) United States
(12) Patent Application Publication
(10) Pub. No.: US 2024/0381580 A1
(43) Pub. Date: Nov. 14, 2024

(54) CONTAINER DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/657,351

(22) Filed: May 7, 2024

(30) Foreign Application Priority Data
May 11, 2023 (CN) 202310531843.3

(51) Int. Cl. H05K 7/20; H05K 7/14

(52) U.S. Cl. CPC H05K 7/20609; H05K 7/1494; H05K 7/1497; H05K 7/2039

(57) ABSTRACT

The present disclosure discloses a container data center, which includes an outdoor unit arrangement region, a power distribution region, and an IT equipment region. Each of the regions sequentially divides adjacent regions from each other by means of shared partitions, and a main entry buffer region and a monitoring platform are arranged between a unique entrance/exit inside a container body and the IT equipment region to control temperature and humidity of each of the regions inside the container body.

### CROSS REFERENCE TO RELATED APPLICATION

This application claims priority to Chinese Patent Application No. 202310531843.3 titled “CONTAINER DATA CENTER” and filed to the China National Intellectual Property Administration on May 11, 2023, the entire contents of which are incorporated herein by reference.

### TECHNICAL FIELD

The present disclosure relates to the field of data center technology, and more particularly, to a container data center facilitating control of temperature and humidity.

### BACKGROUND

With the rapid development of informatization, users have increasingly higher demands for network data processing. As a standardized module, traditional container data centers can integrate IT equipment such as computing, storage and network resources and infrastructure such as racks, refrigeration systems, power distribution cabinets and monitoring facilities into a standard freight container. The container data centers have developed rapidly due to their convenient transportation and high scenario practicality.

In the container data centers, the IT equipment need to perform a large amount of calculations to complete data delivery, such that the data can reach end users faster. Therefore, it is required to create stable temperature and humidity in the environment to reduce adverse impacts of temperature fluctuation on server performance, thereby ensuring normal and stable operation of the IT equipment, and laying an important foundation for ensuring reliability of the container data centers.

At present, the traditional container data centers are not reasonable in space allocation, often requiring unnecessary access of operators, resulting in frequent interaction between internal environment and external environment of the container data centers, causing instability in temperature and humidity inside the container data centers, which further adversely affects operation of the IT equipment, resulting in a decrease in server computing capacity, drop of data delivery speed, and reduction of efficiency.

### SUMMARY

To solve problems in the existing technologies, an embodiment of the present disclosure provides a container data center. The technical solutions are described as follows.

A container data center includes an outdoor unit arrangement region, a power distribution region, and an IT equipment region. Each of the regions sequentially divides adjacent regions from each other by means of shared partitions, and a main entry buffer region and a monitoring platform are arranged between a unique entrance/exit inside a container body and the IT equipment region to control temperature and humidity of each of the regions inside the container body.

A cabinet and an air conditioner are spaced in the IT equipment region.

Outside the container body corresponding to the power distribution region there is provided with a monitoring screen synchronizing in information with the monitoring platform of the main entry buffer region, where the monitoring screen is configured to display a video image and/or a digital parameter.

An air handling device is arranged in the outdoor unit arrangement region to regulate indoor temperature and humidity of each of the regions. The air handling device includes an air heater, an air cooler, an air humidifier, and an air filter. The air humidifier adopting a double wet-film structure with an upper layer and a lower layer.

Further, the air humidifier includes a shell, an upper evaporative water distributor, an upper evaporative wet film, a lower evaporative water distributor, a lower evaporative wet film, an evaporative water collection tray, and an evaporative water storage tank. The upper evaporative water distributor, the upper evaporative wet film, the lower evaporative water distributor, the lower evaporative wet film, the evaporative water collection tray and the evaporative water storage tank are arranged inside the shell.

The upper evaporative wet film and the lower evaporative wet film are arranged at an air inlet of the shell, the upper evaporative water distributor is positioned above the upper evaporative wet film, the lower evaporative water distributor is positioned below the upper evaporative wet film, the lower evaporative wet film is positioned below the lower evaporative water distributor, the evaporative water collection tray is positioned below the lower evaporative wet film, and the evaporative water storage tank is positioned below the evaporative water collection tray. The upper evaporative water distributor is communicated with a hot-end outlet of a plate heat exchanger, a hot-end inlet of the plate heat exchanger is communicated with a circulating water pump and the evaporative water storage tank in sequence, a cold-end inlet of the plate heat exchanger is communicated with an external hot water source, and a cold-end outlet of the plate heat exchanger provides cold water to outside. A fan is positioned at an air outlet of the shell.

Further, the air humidifier also includes a gas-liquid heat exchanger.

The gas-liquid heat exchanger is positioned in front of an air feed direction of the lower evaporative wet film, where one end of the gas-liquid heat exchanger is communicated with the cold-end outlet of the plate heat exchanger, and other end of the gas-liquid heat exchanger provides the cold water to the outside. After exchanging heat in the plate heat exchanger, the air-conditioning circulating water is transported to the gas-liquid heat exchanger to exchange heat with external air in the gas-liquid heat exchanger.

Further, the power distribution region, the IT equipment region, and the main entry buffer region are provided with at least one movable auxiliary humidification device serving as standby equipment to regulate the indoor temperature and humidity of each of the regions.

Further, the movable auxiliary humidification device includes a double wet-film evaporative cooler.

Further, each of the shared partitions is provided with at least one entrance/exit communicating adjacent two regions.

Further, a cold channel and a hot channel allowing at least one person to pass through are reserved on a left side and a right side of the IT equipment region, corresponding to the entrance/exit on a left side and a right side of the power distribution region, respectively.

Further, electrical connections for operation of each equipment are arranged below equipment within the IT equipment region and the power distribution region and arranged for upper and lower wires on an inner wall position at a top of the container body. Further, at least one auxiliary heat dissipation device is coupled to walls on two sides of the outdoor unit arrangement region.

Further, the auxiliary heat dissipation device includes an electric louver.

Beneficial effects of the technical solutions provided by the embodiments of the present disclosure are as below. In the embodiments of the present disclosure, the container data center includes an outdoor unit arrangement region, a power distribution region, and an IT equipment region. Each of the regions sequentially divides adjacent regions from each other by means of shared partitions, and a main entry buffer region and a monitoring platform are arranged between a unique entrance/exit inside a container body and the IT equipment region to control temperature and humidity of each of the regions inside the container body. In this way, according to the present disclosure, the regions within the container data center are divided by functions, and the main entry buffer region is arranged between external environment of the container and the IT equipment region, thereby avoiding adversely affecting stable operation of the equipment by interaction between internal environment and the external environment of a container body. Moreover, the main entry buffer region is also provided with the monitoring platform that can synchronize with a monitoring screen arranged outside the container body corresponding to the power distribution region. Before entering the container data center, an operator can determine, in advance, whether it is needed to get in and out of the relevant operating region according to images and digital parameters, thereby maintaining a stable temperature and humidity environment inside the container body to meet requirements of operating environment.

### BRIEF DESCRIPTION OF THE DRAWINGS

To describe the technical solutions in the embodiments of the present disclosure more clearly, the following will briefly introduce the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a top view of a container data center according to an embodiment of the present disclosure;

FIG. 2 is a side view of a container data center according to an embodiment of the present disclosure;

FIG. 3 is a double wet-film evaporative cooler for an air humidifier in an air handling device of a container data center according to an embodiment of the present disclosure; and

FIG. 4 is a three-dimensional view of a movable wet-film cabinet humidifier used in a container data center according to an embodiment of the present disclosure.

### DETAILED DESCRIPTION

To make the objects, technical solutions and advantages of the present disclosure clearer, the implementation of the present disclosure is further described as below in details with reference to the accompanying drawings.

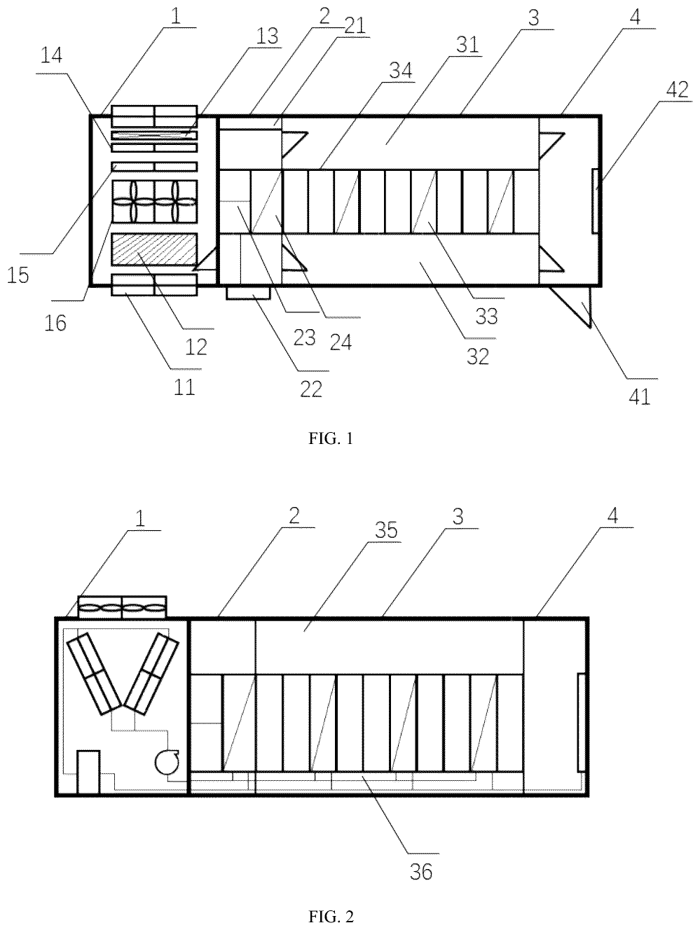

An embodiment of the present disclosure provides a container data center, which is divided, as shown in FIG. 1, into four parts: an outdoor unit arrangement region 1, a power distribution region 2, an IT equipment region 3, and a main entry buffer region 4. The main entry buffer region 4 is positioned at one end of a container body of the container data center, and a unique access door 41 for entering the container data center is provided on one side of the container body, to avoid frequent interaction between internal environment and external environment, resulting in unstable temperature and humidity inside the container body. After an operator enters the access door 41, there are the main entry buffer region 4, the IT equipment region 3, the power distribution region 2, and the outdoor unit arrangement region 1 in sequence. Partition walls are provided between the regions inside the container body, and these regions are connected to each other through the partition walls and are independent of each other. Each partition wall has at least one entrance/exit, facilitating equipment installation and maintenance, and personnel access.

Two entrances/exits are arranged on a left side and a right side of the partition wall between the main entry buffer region 4 and the IT equipment region 3, corresponding to a cold channel 32 and a hot channel 31 of the IT equipment region 3, respectively. A monitoring platform 42 is arranged on a wall opposite the partition wall between the main entry buffer region 4 and the IT equipment region 3, including a display screen and an automatic temperature and humidity monitoring system. Working environment and temperature and humidity data of each region inside the container body of the container data center may be monitored according to video images and digital parameters, to avoid direct contact between external environment and the IT equipment region 3, thereby avoiding adversely affecting stability of temperature and humidity inside the container body.

At least seven cabinets 34 and three air conditioners 33 consistent in sizes and specifications are arranged in a middle of the IT equipment region 3. A length of the IT equipment region adapts to arrangement of IT equipment, which is an adaptive length according to a size of an area occupied by the IT equipment. The cold channel 32 and the hot channel 31 allowing at least one person to pass through are reserved on a left side and a right side of the IT equipment region, corresponding to the entrance/exit on a left side and a right side of the power distribution region 2, respectively.

At least two power distribution cabinets 23 and one air conditioner 24 are arranged in a middle of the power distribution region 2. An entrance hole 21 is provided on a right side of the power distribution region 2 to facilitate circuit connection, and one entrance/exit is provided on the partition wall, separating from the outdoor unit arrangement region 1, on a left side of the power distribution region 2. A monitoring screen 22 is arranged in a prominent position outside the container body corresponding to the power distribution region 2, where the monitoring screen 22 can synchronize some functions of the monitoring platform 42 of the main entry buffer region 4. That is, the monitoring screen 22 has access to synchronously viewing the video images and the temperature and humidity digital parameters of the operating environment in each region of the container body of the container data center collected by the monitoring platform 42 of the main entry buffer region 4, making it convenient to observe whether the operating environment is safe and normal, and to determine whether it is necessary for an operator to enter the container to carry out adjustment operations.

The outdoor unit arrangement region 1 is provided with an air handling unit, also known as an air conditioning unit, which includes at least one air heater 15, at least one air cooler 14, an air humidifier 13, an air filter 12 for purifying air, an air mixing box (not shown in the figure) for regulating fresh air and return air, and a muffler (not shown in the figure) for reducing fan noise. The air handling unit is also provided with two ventilation fans 16, which are arranged on a top outside the container body. According to requirements for annual air conditioning, the unit is provided with an automatic temperature and humidity monitoring system connected to cold and heat sources. The automatic temperature and humidity monitoring system is configured to adjust temperature, humidity, and cleanliness of the air in various regions inside the container body of the container data center, and to handle status of indoor circulating air. Basic operating processes of the ventilation fan 16 are as follows. The ventilation fan 16 mixes the fresh air from outside with a portion of the indoor return air, then the air filter 12 filters out harmful substances in the mixed air, such as dust, smoke dust, black smoke, and organic particles, etc. Next, the filtered air is conveyed to the air cooler 14 or the air heater 15 for cooling or heating to achieve appropriate temperature and humidity. Finally, the cooled or heated air is conveyed to each region through pipelines arranged for lower wires in reserved space below equipment racks in the container body and air conditioners.

The air humidifier 13 commonly used in the air handling unit is generally designed with a single wet film humidification, which has smaller temperature difference between an upper segment and a lower segment of the wet film. Its operating principles are as below. Water is evenly distributed through a wet-film water distributor. Under the action of gravity, the water flows downwards along a surface of the wet film, and wets the surface of the wet film. The unevaporated water from the wet film enters the water storage tank, and is then sent to the top of the wet film by the circulating water pump. This process is repeated. However, due to larger amount of air heat that needs to be absorbed from a liquid state to a gaseous state, in most cases, the water flows from the top to the bottom of the wet film before it is vaporized. At this moment, although water temperature increases, the water flows away in vain. That is, evaporation efficiency of the circulating water at an upper part is not high enough, and direct heat exchange efficiency of the circulating water at a lower part is not high enough, which not only causes energy waste but also fails to reach predetermined humidification amount. Further, to achieve a faster indoor humidification with appropriate humidity at a lower energy consumption, the air humidifier 13 of the air handling unit is designed with a double wet-film structure with an upper layer and a lower layer, and a heat exchanger is arranged in front of a lower wet film to increase its evaporative cooling function, which is hereinafter referred to as a double wet-film evaporative cooler. In this way, the temperature of the circulating water in an upper wet film is higher, which increases the evaporation efficiency of the circulating water in the upper wet film. The temperature of air entering the lower wet film is also lower, and gas-liquid heat exchange of the circulating water in the lower wet film further reduces the water temperature. Furthermore, closed circulation of cooling water is achieved by means of plate heat exchanger. Low-temperature water subjected to evaporative cooling exchanges heat with external hot water, thereby achieving closed cooling of external hot circulating water.

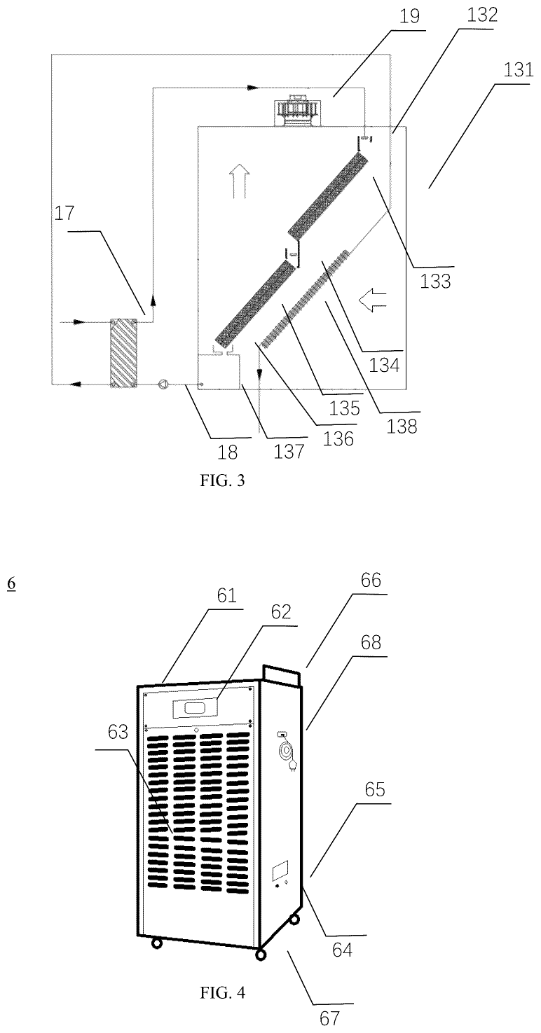

Specifically, as shown in FIG. 3, the double wet-film evaporative cooler includes a shell 131, an upper evaporative water distributor 132, an upper evaporative wet film 133, a lower evaporative water distributor 134, a lower evaporative wet film 135, an evaporative water collection tray 136, and an evaporative water storage tank 137. The upper evaporative water distributor 132, the upper evaporative wet film 133, the lower evaporative water distributor 134, the lower evaporative wet film 135, the evaporative water collection tray 136 and the evaporative water storage tank 137 are arranged inside the shell 131. The upper evaporative wet film 133 and the lower evaporative wet film 135 are arranged near an air inlet of the shell 131. The upper evaporative water distributor 132 is positioned above the upper evaporative wet film 133, the lower evaporative water distributor 134 is positioned below the upper evaporative wet film 133, and the lower evaporative wet film 135 is positioned below the lower evaporative water distributor 134. The gas-liquid heat exchanger 138 is positioned in front of an air feed direction of the lower evaporative wet film 135. The evaporative water collection tray 136 is positioned below the lower evaporative wet film 135, and the evaporative water storage tank 137 is positioned below the evaporative water collection tray 136. The upper evaporative water distributor 132 is communicated with a hot-end outlet of a plate heat exchanger 17, and a hot-end inlet of the plate heat exchanger 17 is communicated with a circulating water pump 18 and the evaporative water storage tank 137 in sequence. A cold-end inlet of the plate heat exchanger 17 is communicated with an external hot water source, and a cold-end outlet of the plate heat exchanger 17 provides cold water to outside. A fan 19 is positioned at an air outlet of the shell 131. External hot water from the air conditioner enters the plate heat exchanger 17 through the cold-end inlet of the plate heat exchanger 17 to carry out heat exchange with cold water entering from the hot-end inlet of the plate heat exchanger 17. After the external hot water from the air conditioner is cooled, it is outputted from the cold-end outlet of the plate heat exchanger 17 and transported to the air conditioner for recycling. After the heat exchange, the circulating cold water is outputted from the hot-end outlet of the plate heat exchanger 17 to the upper evaporative water distributor 132. The circulating cold water undergoes evaporative heat exchange and direct heat exchange with upper air in the upper evaporative wet film 133. After heat exchange and cooling, the circulating cold water flows into the lower evaporative water distributor 134. The lower evaporative water distributor 134 sprays the lower evaporative wet film 135, and performs evaporative heat exchange and direct heat exchange again. The circulating cold water is further cooled down and is collected in the evaporative water collection tray 136 and then flows into the evaporative water storage tank 137, and then is transported to the hot-end inlet of the plate heat exchanger 17 through the circulating water pump 18 to enter the plate heat exchanger 17. After exchanging heat with air-conditioning circulating water, the circulating cold water is first transported to the upper evaporative wet film 133, resulting in a higher temperature of the circulating cold water in the upper evaporative wet film 133. In this way, the external air at higher temperature and the circulating cold water at higher temperature have higher evaporation efficiency in the upper evaporative wet film 133, which can faster increase indoor humidity, and higher direct heat exchange efficiency can be achieved in the lower evaporative wet film 135, thus the circulating cold water at lower temperature can be obtained. The cooling efficiency of the air-conditioning circulating water can be further improved by means of plate heat exchange between the circulating cold water at lower temperature and the air-conditioning circulating water. To further reduce the temperature of the air-conditioning circulating water, preferably the double wet-film evaporative cooler also includes a gas-liquid heat exchanger 138, which is positioned in front of the lower evaporative wet film 135, where one end of the gas-liquid heat exchanger 138 is communicated with the cold-end outlet of the plate heat exchanger 17, and other end of the gas-liquid heat exchanger 138 provides the cold water to the outside. After exchanging heat in the plate heat exchanger 17, the air-conditioning circulating water is transported to the gas-liquid heat exchanger 138 to exchange heat with external air in the gas-liquid heat exchanger 138, to achieve further sufficient cooling. In the evaporative cooling process of the double wet-film evaporative cooler, water is used as a refrigerant, which has no pollution to atmospheric environment. Further, with the use of the air handling unit, the fresh air may be directly used to improve indoor air quality.

The air handling unit has the advantages of less space occupation, larger air capacity, higher air quality, lower noise, and lower energy consumption. At least one electric louver 11 may be coupled to left and right walls of the container body in the outdoor unit arrangement region 1, which can further assist in heat dissipation. There is provided an entrance/exit on the left side of the partition wall between the power distribution region 2 and the outdoor unit arrangement region 1, which is convenient for operators to enter.

The double wet-film evaporative cooler may also be designed as a movable wet-film cabinet humidifier 6 as shown in FIG. 4, including a shell 61, a double wet-film evaporative cooler (not shown in the figure), a display screen 62, an air outlet 63, a water inlet 64, a water outlet 65, an armrest 66, a universal wheel 67, and a power supply 68, etc. What is displayed on the display screen 62 of the movable wet-film cabinet humidifier 6 includes, but is not limited to, water storage capacity during operation of the movable wet-film cabinet humidifier 6. The double wet-film evaporative cooler is arranged in the movable wet-film cabinet humidifier. When the indoor humidity inside the power distribution region 2, the IT equipment region 3 and the main entry buffer region 4 fail to meet requirement, the movable wet-film cabinet humidifier as shown in FIG. 4 may be arranged in each region according to the needs, and the movable wet-film cabinet humidifier may be directly used by connecting the power supply 68, which further assists in humidification and cooling in each region. The movable wet-film cabinet humidifier 6 is connected to the automatic temperature and humidity monitoring system of the container data center through, but not limited to, Bluetooth, wireless, and other manners. The monitoring platform 42 of the main entry buffer region 4 displays equipment information during operation, such that the operators can make judgments and operational decisions about operating environment. The movable wet-film cabinet humidifier 6 is free of white-powder phenomenon in use, simple in structure, low in energy consumption, has no special requirements for water quality, and provides clean humidification to the air. Furthermore, the movable wet-film cabinet humidifier 6 is short in humidification distance, small in volume, flexible in use, convenient for maintenance, and good in cooling and humidification effects.

As shown in FIG. 2, without affecting use of left and right channels, space is reserved on top inner walls and outer surfaces of the container body of the container data center and below racks of various equipment inside the container body to arrange upper wires 35 and lower wires 36, and to arrange circuits and pipelines for operation of various equipment inside the container body, including air-conditioning control circuits in the power distribution region 2 and the IT equipment region 3. In this way, adjustment of air temperature, humidity, and cleanliness in various regions inside the container body of the container data center is realized, and adverse impacts caused by interaction between internal environment and external environment are reduced, such that a safe and stable state is achieved.

In the embodiments of the present disclosure, the container data center includes the outdoor unit arrangement region 1, the power distribution region 2, and the IT equipment region 3. Each of the regions sequentially divides adjacent regions from each other by means of shared partitions, and a main entry buffer region 4 and a monitoring platform 42 are arranged between a unique entrance/exit inside the container body and the IT equipment region 3 to control temperature and humidity of each of the regions inside the container body. In this way, according to the present disclosure, the regions within the container data center are divided by functions, and the main entry buffer region 4 is arranged between the external environment of the container and the IT equipment region 3, thereby avoiding adversely affecting stable operation of the equipment by interaction between the internal environment and the external environment of the container body. Moreover, the main entry buffer region 4 is also provided with the monitoring platform 42 that can synchronize with the monitoring screen 22 arranged outside the container body corresponding to the power distribution region 2. Before entering the container data center, the operators can determine, in advance, whether it is needed to get in and out of the relevant operating region according to images and digital parameters, thereby maintaining a stable temperature and humidity environment inside the container body to meet requirements of operating environment.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. A container data center, comprising an outdoor unit arrangement region, a power distribution region, and an IT equipment region, wherein each of the regions sequentially divides adjacent regions from each other by means of shared partitions, and a main entry buffer region and a monitoring platform are arranged between a unique entrance/exit inside a container body and the IT equipment region to control temperature and humidity of each of the regions inside the container body;
a cabinet and an air conditioner are spaced in the IT equipment region;
outside the container body corresponding to the power distribution region there is provided with a monitoring screen synchronizing in information with the monitoring platform of the main entry buffer region, the monitoring screen being configured to display a video image and/or a digital parameter; and
an air handling device is arranged in the outdoor unit arrangement region to regulate indoor temperature and humidity of each of the regions; the air handling device comprises an air heater, an air cooler, an air humidifier, and an air filter, the air humidifier adopting a double wet-film structure with an upper layer and a lower layer.

2. The container data center according to claim 1, wherein the air humidifier comprises a shell, an upper evaporative water distributor, an upper evaporative wet film, a lower evaporative water distributor, a lower evaporative wet film, an evaporative water collection tray, and an evaporative water storage tank, the upper evaporative water distributor, the upper evaporative wet film, the lower evaporative water distributor, the lower evaporative wet film, the evaporative water collection tray and the evaporative water storage tank being arranged inside the shell; and
the upper evaporative wet film and the lower evaporative wet film are arranged at an air inlet of the shell, the upper evaporative water distributor is positioned above the upper evaporative wet film, the lower evaporative water distributor is positioned below the upper evaporative wet film, the lower evaporative wet film is positioned below the lower evaporative water distributor, the evaporative water collection tray is positioned below the lower evaporative wet film, the evaporative water storage tank is positioned below the evaporative water collection tray, the upper evaporative water distributor is communicated with a hot-end outlet of a plate heat exchanger, a hot-end inlet of the plate heat exchanger is communicated with a circulating water pump and the evaporative water storage tank in sequence, a cold-end inlet of the plate heat exchanger is communicated with an external hot water source, and a cold-end outlet of the plate heat exchanger provides cold water to outside; and a fan is positioned at an air outlet of the shell.

3. The container data center according to claim 2, wherein the air humidifier further comprises a gas-liquid heat exchanger; and
the gas-liquid heat exchanger is positioned in front of an air feed direction of the lower evaporative wet film, one end of the gas-liquid heat exchanger is communicated with the cold-end outlet of the plate heat exchanger, and other end of the gas-liquid heat exchanger provides the cold water to the outside; and after exchanging heat in the plate heat exchanger, the air-conditioning circulating water is transported to the gas-liquid heat exchanger to exchange heat with external air in the gas-liquid heat exchanger.

4. The container data center according to claim 1, wherein the power distribution region, the IT equipment region, and the main entry buffer region are provided with at least one movable auxiliary humidification device serving as standby equipment to regulate the indoor temperature and humidity of each of the regions.

5. The container data center according to claim 4, wherein the movable auxiliary humidification device comprises a double wet-film evaporative cooler.

6. The container data center according to claim 1, wherein each of the shared partitions is provided with at least one entrance/exit communicating adjacent two of the regions.

7. The container data center according to claim 1, wherein a cold channel and a hot channel allowing at least one person to pass through are reserved on a left side and a right side of the IT equipment region, corresponding to the entrance/exit on a left side and a right side of the power distribution region, respectively.

8. The container data center according to claim 1, wherein electrical connections for operation of each equipment are arranged below equipment within the IT equipment region and the power distribution region and arranged for upper and lower wires on an inner wall position at a top of the container body.

9. The container data center according to claim 1, wherein at least one auxiliary heat dissipation device is coupled to walls on two sides of the outdoor unit arrangement region.

10. The container data center according to claim 9, wherein the auxiliary heat dissipation device comprises an electric louver.
